(19) United States
(12) Patent Application Publication
(10) Pub. No.: US 2022/0172669 A1
(43) Pub. Date: Jun. 2, 2022

(54) MICRO LIGHT-EMITTING DIODE DISPLAY DEVICE

(71) Applicant: PlayNitride Display Co., Ltd., Zhunan Township (TW)

(72) Inventors: Ying-Tsang LIU, Zhunan Township (TW); Kuan-Yung LIAO, Zhunan Township (TW)

(21) Appl. No.: 17/205,489

(22) Filed: Mar. 18, 2021

(30) Foreign Application Priority Data
Nov. 30, 2020 (TW) 109142080

(51) Int. Cl. G09G 3/32

(52) U.S. Cl. CPC G09G 3/32; H01L 25/167

(57) ABSTRACT

A micro light-emitting diode display device includes a display panel and a driving circuit unit. The display panel includes a plurality of pixel group units arranged side by side along a first direction, and each pixel group unit includes a plurality of pixels extending in a second direction. The driving circuit unit outputs a first voltage and a second voltage different from the first voltage to the pixels of each pixel group unit of the display panel. The display panel has a first side and a second side disposed in the second direction and opposite to each other. The first voltage is introduced into the display panel from the first side, and the second voltage is introduced into the display panel from the second side. The voltage bias between the first voltage and the second voltage is in positive correlation to the brightness of one of the connected pixels.

### CROSS REFERENCE TO RELATED APPLICATIONS

This Non-provisional application claims priority under 35 U.S.C. § 119(a) on Patent Application No(s). 109142080 filed in Taiwan, Republic of China on Nov. 30, 2020, the entire contents of which are hereby incorporated by reference.

### BACKGROUND

### Technology Field

The present disclosure relates to a display device and, in particular, to a micro light-emitting diode (LED) display device.

### Description of Related Art

When the world is paying attention to future display technologies, the micro LED is one of the most promising technologies. In brief, the micro LED is a technology combining miniaturizing and matrix of LEDs, thereby placing millions or even tens of millions of dies, which are smaller than 100 microns and thinner than a hair, on a substrate. Compared with the current OLED (organic light-emitting diode) display technology, the micro LED is also self-luminous, but it does not have the most deadly “screen burn-in” problem of OLED due to the different materials used. In addition, the micro LED further has the advantages of low power consumption, high contrast, wide color gamut, high brightness, small size, thin, light weight, energy saving, etc. Therefore, major manufacturers around the world are scrambling to invest in the research and development of micro LED technology.

However, although micro LED has many advantages, there are still some technical obstacles to be overcome. For example, in a large-size, high-resolution, and high-frequency micro LED display device, the driving voltages inputted to pixels may generate voltage drops due to the different positions of pixels in the panel, and the generated voltage drops can cause uneven brightness. This is still a non-ignorable issue in the micro LED display devices.

Therefore, it is desired to provide a micro LED display device that can solve the uneven brightness problem caused by the voltage drops of driving voltages, thereby improving the display quality.

### SUMMARY

In view of the foregoing, the present disclosure is to provide a micro LED display device that can improve the uneven brightness phenomenon caused by the voltage drops of driving voltages, thereby improving the display quality.

To achieve the above, a micro LED display device of this disclosure comprises a display panel and a driving circuit unit. The display panel comprises a plurality of pixel group units arranged side by side along a first direction. Each of the pixel group units comprises a plurality of pixels extending in a second direction, and the first direction is different from the second direction. The driving circuit unit is electrically connected to the display panel. The driving circuit unit outputs a first voltage and a second voltage different from the first voltage to the pixels of each pixel group unit of the display panel. The display panel has a first side and a second side disposed in the second direction and opposite to each other. The first voltage is introduced into the display panel from the first side, and the second voltage is introduced into the display panel from the second side. The voltage bias between the first voltage and the second voltage is in positive correlation to a brightness of one of the connected pixels.

In one embodiment, the first voltage is greater than the second voltage.

In one embodiment, the first voltage is a driving voltage of the pixel group units, and the second voltage is a common voltage of the pixel group units.

In one embodiment, the first voltage is applied along the second direction to the pixels of each of the pixel group units.

In one embodiment, the second voltage is applied along a direction opposite to the second direction to the pixels of each of the pixel group units.

In one embodiment, the display panel further comprises a plurality of first connecting lines extending along the second direction, and the first voltage is applied to the pixel group units through the first connecting lines.

In one embodiment, one of the first connecting lines is disposed corresponding to one of the pixel group units.

In one embodiment, the display panel further comprises a plurality of second connecting lines extending along the second direction, and the second voltage is applied to the pixel group units through the second connecting lines along a direction opposite to the second direction.

In one embodiment, one of the second connecting lines is disposed corresponding to one of the pixel group units.

In one embodiment, the micro LED display device further comprises at least one main trace arranged between the driving circuit unit and the second connecting lines, and the second voltage is introduced into the display panel from the second side through the at least one main trace.

In one embodiment, the at least one main trace is connected to each of the second connecting lines.

In one embodiment, the micro LED display device comprises a plurality of main traces, the pixel group units are divided into a plurality of zones in the first direction, and the main traces are disposed corresponding to the zones.

In one embodiment, each of the zones includes a plurality of the second connecting lines and electrically connects to one of the main traces.

In one embodiment, the micro LED display device comprises a plurality of main traces, and the main traces are disposed corresponding to the second connecting lines.

In one embodiment, the micro LED display device further comprises a plurality of data lines, the driving circuit unit comprises a data driving circuit and a power supply circuit, the data driving circuit outputs a data signal to the pixel group units through the data lines, and the power supply circuit outputs the first voltage and the second voltage.

In one embodiment, the micro LED display device further comprises a plurality of scan lines, and the driving circuit unit comprises a scan driving circuit electrically connected to the display panel and outputs a scan signal to the pixel group units through the scan lines.

As mentioned above, in the micro LED display device of this disclosure, the display panel comprises a plurality of pixel group units arranged side by side along a first direction, and each of the pixel group units comprises a plurality of pixels extending in a second direction, which is different from the first direction; and the driving circuit unit outputs a first voltage and a second voltage to the pixels of each pixel group unit of the display panel, wherein the first voltage is introduced into the display panel from the first side of the display panel, the second voltage is introduced into the display panel from the second side of the display panel, and the voltage bias between the first voltage and the second voltage is in positive correlation to a brightness of one of the connected pixels. Accordingly, the voltage bias for driving the micro LEDs, which are added in different pixels of each pixel group unit along the second direction, can have a small deviation, thereby minimizing the deviation of the brightness of the micro LEDs of each pixel group unit. Therefore, the micro LED display device of this disclosure can improve the uneven brightness phenomenon caused by the voltage drops of driving voltages, thereby improving the display quality.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a schematic diagram showing a micro LED display device according to an embodiment of this disclosure;

FIG. 2 is a schematic circuit diagram of four adjacent pixels in two pixel group units of the micro LED display device of FIG. 1;

FIG. 3 is a schematic diagram showing the voltage drops of the driving voltages for pixels in different positions of one of the pixel group units of a conventional micro LED display device;

FIG. 4 is a schematic diagram showing the voltage drops of the driving voltages for pixels in different positions of one of the pixel group units of the micro LED display device as shown in FIG. 1;

FIG. 5 is a schematic diagram showing the voltage drops of the driving voltages for the pixels in different positions of one of the pixel group units of the conventional micro LED display device and the micro LED display device of this disclosure; and

FIG. 6 is a schematic diagram showing a micro LED display device according to another embodiment of this disclosure.

### DETAILED DESCRIPTION OF THE DISCLOSURE

The present disclosure will be apparent from the following detailed description, which proceeds with reference to the accompanying drawings, wherein the same references relate to the same elements.

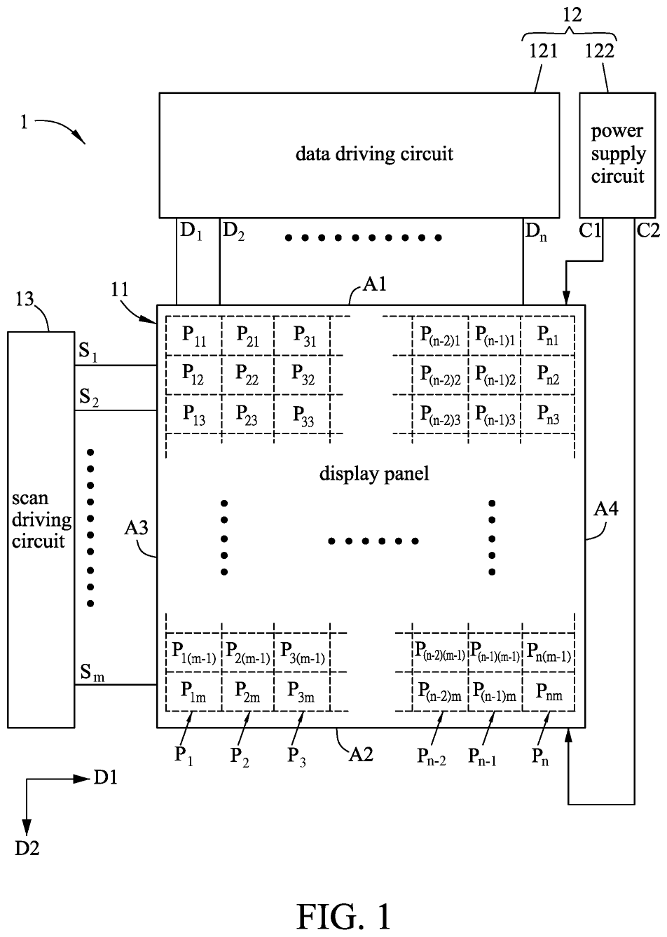

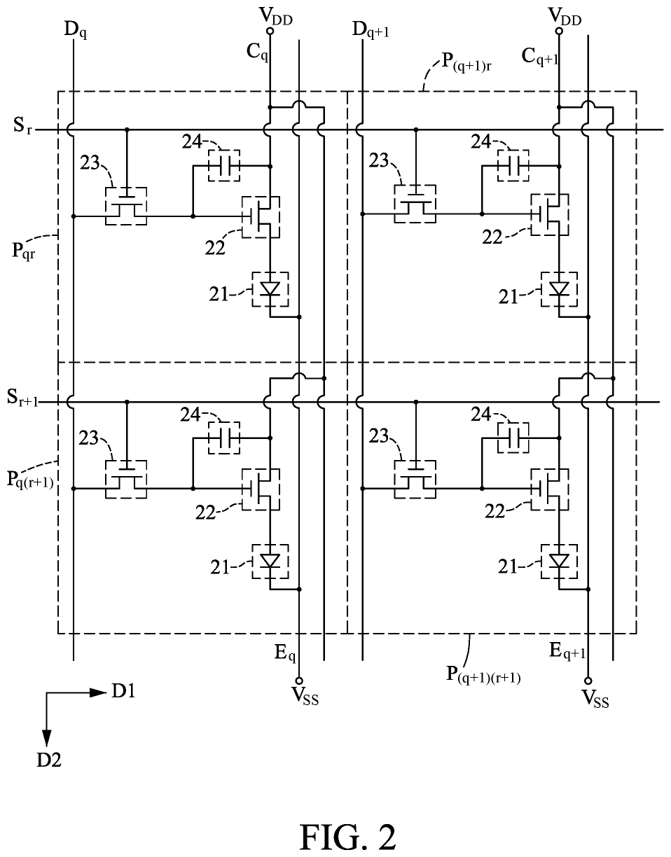

FIG. 1 is a schematic diagram showing a micro LED display device according to an embodiment of this disclosure, and FIG. 2 is a schematic circuit diagram of four adjacent pixels in two pixel group units of the micro LED display device of FIG. 1.

Referring to FIGS. 1 and 2, the micro LED display device 1 of this embodiment is an AM (active matrix) micro LED display device, which comprises a display panel 11 and a driving circuit unit 12. In addition, the micro LED display device 1 of this embodiment can further comprise a scan driving circuit 13.

The display panel 11 is a micro LED display panel, which comprises a plurality of micro LEDs. When the micro LEDs are driven individually by the driving circuit unit 12 to emit light, the display panel 11 can display an image. In this embodiment, the display panel 11 comprises a plurality of pixel group units P₁˜Pₙ arranged side by side along a first direction D1, wherein n is a positive integer greater than 1. Each of the pixel group units P₁˜Pₙ comprises a plurality of pixels extending in a second direction D2, and the first direction D1 is different from the second direction D2. In this embodiment, the first direction D1 is perpendicular to the second direction D2, but this disclosure is not limited thereto. In another embodiment, the first direction D1 is not perpendicular to the second direction D2, and the included angle between the first direction D1 and the second direction D2 is, for example, an acute angle.

Specifically, the pixel group units P₁˜Pₙ are arranged side by side along the first direction D1 (e.g. a horizontal direction herein) and disposed in the display area of the display panel 11, and each of the pixel group units P₁˜Pₙ comprises a plurality of pixels extending in arranged along the second direction D2 (e.g. a vertical direction herein). Each pixel comprises at least one micro LED. In this embodiment, each pixel is correspondingly configured with one monochromatic micro LED (a single color), so that three adjacent pixels with different colors (e.g. red, green and blue). In other words, three adjacent RGB pixels can construct a single full-color pixel point. To be noted, each pixel group unit indicates the pixels arranged along one data line and connected to the same data line.

The pixel group unit P₁ comprises the pixels P₁₁˜P₁ₘ extending in and arranged along the second direction D2, wherein m is a positive integer greater than 1. Similarly, the pixel group unit Pₙ₋₂ comprises the pixels P₍ₙ₋₂₎₁˜P₍ₙ₋₂₎ₘ extending in and arranged along the second direction D2. Since the pixel group units P₁˜Pₙ are arranged side by side along the first direction D1, and each of the pixel group units P₁˜Pₙ comprises m pixels extending in and arranged along the second direction D2, the display panel 11 comprises totally n×m pixels P₁₁˜Pₙₘ. In this embodiment, the pixels P₁₁˜Pₙₘ of the display panel 11 are arranged in an array including n columns (the second direction D2) and m rows (the first direction D1). In addition, the display panel 11 further comprises a first side A1, a second side A2, a third side A3, and a fourth side A4. The first side A1 and the second side A2 are disposed opposite to each other in the second direction D2, and the third side A3 and the fourth side A4 are disposed opposite to each other in the first direction D1. The third side A3 is connected to the first side A1 and the second side A2, and the fourth side A4 is also connected to the first side A1 and the second side A2.

The driving circuit unit 12 is disposed next to the first side A1 of the display panel 11 and is electrically connected to the display panel 11. In this embodiment, the driving circuit unit 12 outputs a first voltage V_{DD} and a second voltage V_{SS} to the pixels of each of the pixel group units P₁˜Pₙ of the display panel 11. The first voltage V_{DD} is introduced into the display panel 11 from the first side A1 of the display panel 11, and the second voltage V_{SS} is introduced into the display panel 11 from the second side A2 of the display panel 11. The voltage bias between the first voltage V_{DD} and the second voltage V_{SS} is in positive correlation to a brightness of one of the connected pixels. Herein, the term “the voltage bias between the first voltage V_{DD} and the second voltage V_{SS} is in positive correlation to a brightness of one of the connected pixels” means that the brightness of the corresponding pixel is relatively higher while the voltage bias between the first voltage V_{DD} and the second voltage V_{SS} is larger, and the brightness of the corresponding pixel is relatively lower while the voltage bias between the first voltage V_{DD} and the second voltage V_{SS} is smaller.

Specifically, the driving circuit unit 12 of this embodiment comprises a data driving circuit 121 and a power supply circuit 122. The power supply circuit 122 provides the first voltage V_{DD} and the second voltage V_{SS}. The first voltage V_{DD} is a DC driving voltage applied to drive the light-emitting elements (i.e. micro LEDs) of the pixels P₁₁˜Pₙₘ of the pixel group units P₁˜Pₙ to emit light, and the second voltage V_{SS} is the common voltage of the pixels P₁₁˜Pₙₘ of the pixel group units P₁˜Pₙ. The first voltage V_{DD} and the second voltage V_{SS} are introduced into the display panel 11 from two opposite sides (sides A1 and A2) of the display panel 11. In addition, the first voltage V_{DD} is greater than the second voltage V_{SS}. In this embodiment, for example, the first voltage V_{DD} is 4.6V, and the second voltage V_{SS} is −2V. To be noted, this disclosure is not limited thereto. In different embodiments, the values of the first voltage V_{DD} and the second voltage V_{SS} can be adjusted based on the characteristics of the micro LEDs to be driven.

The power supply circuit 122 of this embodiment outputs the first voltage V_{DD}, which is introduced into the display panel 11 from the first side A1 of the display panel 11 through one main trace C1, and then transmitted to the pixels P₁₁˜Pₙₘ of the pixel group units P₁˜Pₙ through a plurality of first connecting lines in the display area (e.g. the first connecting lines C_{q} and C_{q+1} as shown in FIG. 2). In this embodiment, the first voltage V_{DD} is sequentially transmitted to the pixels of each of the pixel group units P₁˜Pₙ through the inside first connecting lines along the second direction D2. In addition, the power supply circuit 122 also outputs the second voltage V_{SS}, which is introduced into the display panel 11 from the second side A2 of the display panel 11 through at least one main trace C2. The display panel 11 further comprises a plurality of second connecting lines (e.g. the second connecting lines E_{q} and E_{q+1} as shown in FIG. 2) in the display area. The main trace C2 is connected to all of the second connecting lines, and the second voltage V_{SS} is transmitted to the pixels of the pixel group units P₁˜Pₙ through the main trace C2 and the second connecting lines in a direction opposite to the second direction D2.

In addition, the micro LED display device 1 of this embodiment further comprises a plurality of data lines D₁˜Dₙ, and the data driving circuit 121 is electrically connected to the display panel 11 through the data lines D₁˜Dₙ. Accordingly, the data driving circuit 121 can output a data signal along the second direction D2 and through the data lines D₁˜Dₙ to the pixels P₁₁˜Pₙₘ of each of the pixel group units P₁˜Pₙ of the display panel 11. In addition, the micro LED display device 1 of this embodiment can further comprise a plurality of scan lines S₁˜Sₘ, and the scan driving circuit 13 is disposed next to the third side A3 of the display panel 11 and electrically connected to the display panel 11 through the scan lines S₁˜Sₘ. Accordingly, the scan driving circuit 13 can output a scan signal along the first direction D1 and through the scan lines S₁˜Sₘ to the pixels P₁₁˜Pₙₘ of each of the pixel group units P₁˜Pₙ. In different embodiments, the scan driving circuit 13 can be disposed next to the fourth side A4 of the display panel 11 and electrically connected to the display panel 11 through the scan lines S₁˜Sₘ. Alternatively, the scan driving circuit 13 can comprise two driving sub-circuits, which are disposed next to the third side A3 and the fourth side A4 of the display panel 11, respectively. This disclosure is not limited thereto. In some embodiments, the data driving circuit 121 and the power supply circuit 122 can be two individual driving chips, or they can be integrated as a single driving chip (i.e. the driving circuit unit 12 is a single chip), or the driving circuit unit 12 (including the data driving circuit 121 and the power supply circuit 122) and the scan driving circuit 13 can be integrated as a single driving chip. This disclosure is not limited thereto.

When the scan driving circuit 13 outputs the scan signals through the scan lines S₁˜Sₘ to conduct (turn on) the pixels P₁₁˜Pₙₘ, the data driving circuit 121 can output the data signals to the corresponding pixels of each of the pixel group units P₁˜Pₙ through the data lines D₁˜Dₙ, respectively. Then, the power supply circuit 122 can output the first voltage V_{DD} and the second voltage V_{SS} to the pixels of each of the pixel group units P₁˜Pₙ of the display panel 11 for driving or turning on the micro LEDs of the pixels P₁₁˜Pₙₘ of the pixel group units P₁˜Pₙ, thereby enabling the display device to display images. Herein, the first voltage V_{DD} is introduced into the pixels of each of the pixel group units P₁˜Pₙ from the first side A1 of the display panel 11 through the main trace C1 and the corresponding first connecting lines in the display panel 11, and the second voltage V_{SS} is introduced into the pixels of each of the pixel group units P₁˜Pₙ from the second side A2 of the display panel 11 through the main trace C2 and the corresponding second connecting lines in the display panel 11.

The details of four continuous pixels P_{qr}, P_{q(r+1)}, P_{(q+1)r} and P_{(q+1)(r+1)} in two adjacent pixel group units in the micro LED display device 1 of this embodiment will be described hereinafter with reference to FIG. 2. As shown in FIG. 2, q is between 1 and (n−1) (1≤q≤(n−1)), and r is between 1 and (m−1) (1≤r≤(m−1)). In addition, the pixels P_{qr} and P_{q(r+1)} are arranged along the second direction D2, the pixels P_{(q+1)r} and P_{(q+1)(r+1)} are arranged along the second direction D2, the pixels P_{qr} and P_{(q+1)r} are arranged along the first direction D1, and the pixels P_{q(r+1)} and P_{(q+1)(r+1)} are arranged along the first direction D1. In this embodiment, each of the pixels P_{qr}, P_{q(r+1)}, P_{(q+1)r} and P_{(q+1)(r+1)} is, for example, a 2T1C structure, but this disclosure is not limited thereto. In other embodiments, the pixels can be any of other circuit structures, such as 3T1C, 6T1C, 7T1C or 7T2C.

In this embodiment, the display panel 11 comprises a plurality of connecting lines extending along the second direction D2 (e.g. the first connecting lines C_{q} and C_{q+1} as shown in FIG. 2), and the first voltage V_{DD} is transmitted to the pixels P₁₁˜Pₙₘ of the pixel group units P₁˜Pₙ, through the first connecting lines (e.g. the connecting lines C_{q} and C_{q+1}). Accordingly, the main trace C1 of FIG. 1 is connected to the first connecting lines C_{q} and C_{q+1} of FIG. 2 for transmitting the first voltage V_{DD} to the pixels of the corresponding pixel group units. In this embodiment, the first connecting lines are disposed corresponding to the pixel group units (in a one-by-one manner). In addition, the display panel 11 of this embodiment further comprises a plurality of second connecting lines extending in the second direction D2 (FIG. 2 only shows two second connecting lines E_{q} and E_{q+1}), and the second voltage V_{SS} is transmitted to the pixels P₁₁˜Pₙₘ of the pixel group units P₁˜Pₙ, through the second connecting lines (e.g. the connecting lines E_{q} and E_{q+1}) in a direction opposite to the second direction D2. Accordingly, the main trace C2 of FIG. 1 is connected to the second connecting lines E_{q} and E_{q+1} of FIG. 2 for transmitting the second voltage V_{SS} to the pixels of the corresponding pixel group units. In this embodiment, the second connecting lines are disposed corresponding to the pixel group units (in a one-by-one manner).

To be noted, the terms “main trace”, “first connecting line” or “second connecting line” cam be a physical conductive wire, or any circuit composed of a circuit layer or a conductive layer that can transmit electrical signals (e.g. a thin-film circuit), and this disclosure is not limited.

For example, the pixel P_{qr} comprises a micro LED 21, a driving transistor 22, a switch transistor 23, and a capacitor 24. The driving transistor 22 drives the micro LED 21 to illuminate. The source of the driving transistor 22 is connected to the first connecting line C_{q} and receives the first voltage V_{DD}, the drain of the driving transistor 22 is connected to one terminal of the micro LED 21, and the other terminal of the micro LED 21 is connected to the second connecting line E_{q} for connecting the second voltage V_{SS}. In addition, the gate of the switch transistor 23 is connected to a scan line Sᵣ for receiving a scan signal, the drain of the switch transistor 23 is connected to a data line D_{q} for receiving a data signal, the source of the switch transistor 23 is connected to one terminal of the capacitor 24 and the gate of the driving transistor 22, and the other terminal of the capacitor 24 is connected to the first connecting line C_{q}. Accordingly, the scan signal of the scan line Sᵣ can control to conduct (turn on) the switch transistor 23, so that the data signal of the data line D_{q} can be inputted to the gate of the driving transistor 22 through the switch transistor 23 for conducting the driving transistor 22. After conducting the driving transistor 22, the first voltage V_{DD} can be transmitted to one terminal of the micro LED 21 through the first connecting line C_{q} and the driving transistor 22, thereby forming a voltage bias between two terminals of the micro LED 21. Accordingly, the micro LED 21 of the pixel P_{qr} can be turned on to emit light, and the voltage bias between the first voltage V_{DD} and the second voltage V_{SS} is in positive correlation to the brightness of the connected pixel P_{qr}.

To be noted, the common voltage (the second voltage V_{SS}) of this embodiment is transmitted through each corresponding second connecting line of each pixel group unit to electrically connect to each micro LED.

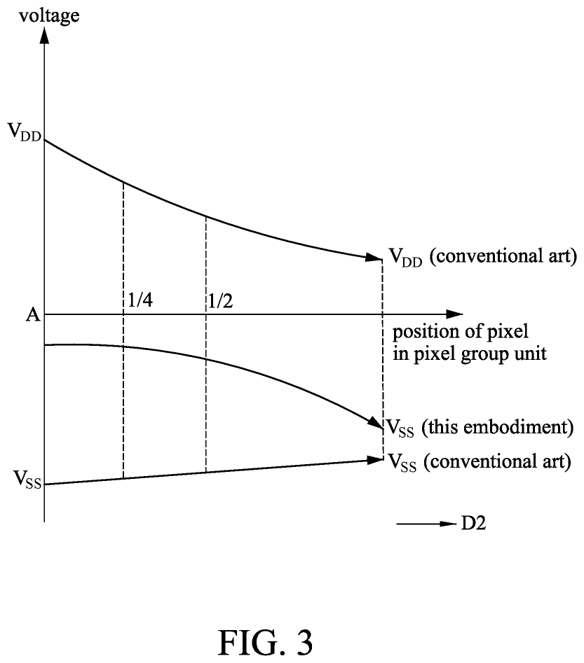

FIG. 3 is a schematic diagram showing the voltage drops of the driving voltages for pixels in different positions of one of the pixel group units of a conventional micro LED display device. As shown in FIG. 3, in the conventional art, the DC driving voltage and the common voltage (also named as the first voltage V_{DD} and the second voltage V_{SS}) outputted through the data driving circuit are introduced into the display panel from the same side of the display panel (e.g. the first side A1). For example, as shown in FIG. 3, the signal input terminal A of the first voltage V_{DD} and the second voltage V_{SS} is disposed at the first side A1. In a large-scaled display panel, the length of each connecting line corresponding to the pixels of each pixel group unit extending in the second direction D2 is very large. Thus, when the first voltage V_{DD} is introduced into the display panel, there are voltage drops due to the inherent impedances of the connecting lines, the parasitic capacitance or any adjacent conducting layer. Accordingly, the voltage differences for driving the micro LEDs, which are located at different positions in the pixel group unit along the second direction D2, are different. As shown in FIG. 3, the voltage bias between the first voltage V_{DD} and the second voltage V_{SS} of the pixel, which is located farther away from the signal input terminal A, is smaller. The various voltage drops can result in the uneven brightness phenomenon of the pixels of each pixel group unit along the vertical direction (the second direction D2), thereby causing the poor display quality.

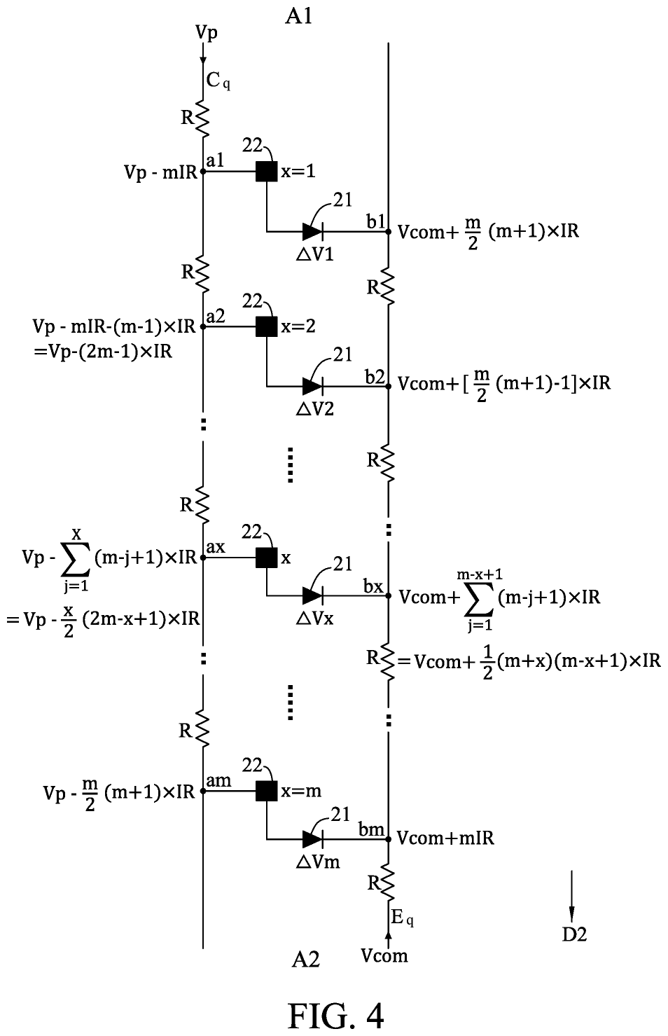

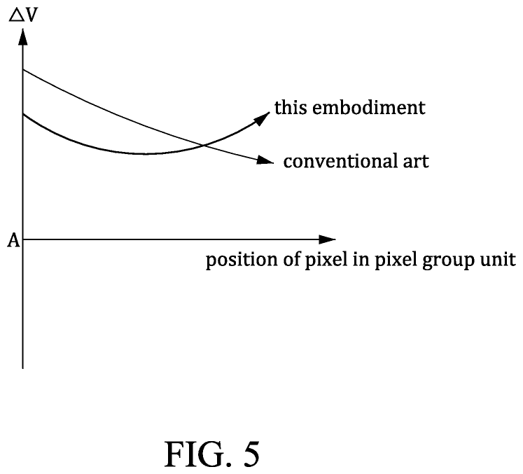

With reference to FIG. 1, in the micro LED display device 1 of this embodiment, the first voltage V_{DD} outputted from the power supply circuit 122 of the driving circuit unit 12 is introduced into the display panel 11 from the first side A1 of the display panel 11, and the second voltage V_{SS} outputted from the power supply circuit 122 is introduced into the display panel 11 from the second side A2 of the display panel 11. Therefore, the voltage drops of the driving voltages for the pixels of each pixel group unit can be referred to FIGS. 4 and 5, wherein FIG. 4 is a schematic diagram showing the voltage drops of the driving voltages for pixels in different positions of one of the pixel group units of the micro LED display device as shown in FIG. 1, and FIG. 5 is a schematic diagram showing the voltage drops of the driving voltages for the pixels in different positions of one of the pixel group units of the conventional micro LED display device and the micro LED display device of this disclosure.

As shown in FIG. 4, Vp represents the peak value of the first voltage V_{DD} (a positive voltage, e.g. 4.6V), which is transmitted in the direction from the first side A1 to the second side A2 of the display panel 11 through the first connecting line C_{q}; Vcom represents the peak value of the second voltage V_{SS} (a negative voltage, e.g. −2V), which is transmitted in the direction from the second side A2 to the first side A1 through the second connecting line E_{q}; x represents the number x pixel along the second direction D2 (total m pixels), so that there are totally m driving transistors 22 and m micro LEDs 21 in each pixel group unit; ΔV1˜ΔVm represent the voltage bias between two terminals ax and bx (wherein x is 1˜m); R represents the impedance of one section of the first connecting line C_{q} or the second connecting line E_{q}; and I represents the current flowing through the impedance R. To be noted, it is assumed that the characteristics of the driving transistors 22 of the pixels are the same, and the currents I flowing through the micro LEDs 21 of the pixels are equal, too.

After calculation, it is found that the voltage bias between two sides of the driving transistors 22 and the micro LEDs 21 in different pixels of each pixel group unit of FIG. 4 have substantially small variations (even almost the same). For example, in the pixel where x=1, the voltage applied to the first connecting line C_{q} connecting to the driving transistor 22 is equal to Vp−mIR, the voltage applied to the second connecting line E_{q} connecting to the micro LED 21 is equal to Vcom+½×m(m+1)×IR, and the voltage bias therebetween is equal to Vp−mIR−Vcom−½×m(m+1)×IR. In the pixel where x=m, the voltage applied to the first connecting line C_{q} connecting to the driving transistor 22 is equal to Vp−½×m(m+1)×IR, the voltage applied to the second connecting line E_{q} connecting to the micro LED 21 is equal to Vcom+mIR, and the voltage bias therebetween is also equal to Vp−mIR−Vcom−½×m(m+1)×IR. In any of the other pixels, the voltage bias between the voltages applied to the first connecting line C_{q} and the second connecting line E_{q} is approximating to the voltage bias of the above-mentioned pixels (where x=1 and x=m).

In an actual application embodiment, for example, when the power supply circuit 122 provides a first voltage V_{DD} of 4.6V and a second voltage V_{SS} of −2V, m is 100, and IR is 0.0001V, in one of the pixel group units extending in the second direction D2, the voltage bias (ΔV) between the voltages applied to the first connection line C_{q} and the second connection line E_{q} of the first pixel (x=1) of the display panel 11 is 6.085V, the voltage bias (ΔV) between the voltages applied to the first connection line C_{q} and the second connection line E_{q} of the pixel located at the ¼ position of the pixel group unit (i.e. the 25^{th} pixel) is 5.905V, the voltage bias (ΔV) between the voltages applied to the first connection line C_{q} and the second connection line E_{q} of the pixel located at the ½ position of the pixel group unit (i.e. the 50^{th} pixel) is 5.84V, and the voltage bias (ΔV) between the voltages applied to the first connection line C_{q} and the second connection line E_{q} of the last pixel of the pixel group unit (i.e. the m^{th} pixel) is 6.085V. The results prove that the design of this disclosure can indeed keep the voltage differences between the voltages bias for driving the driving transistors 22 and the micro LEDs 21 (i.e. the voltages applied to the first connection line C_{q} and the second connection line E_{q}) of different pixels almost the same regardless the distances between the signal input terminal and the pixels. In addition, the voltage bias between the first voltage V_{DD} and the second voltage V_{SS} of pixels at different locations are approximating to each other.

Referring to FIG. 5, ΔV represents the voltage bias between the voltages applied to the first connecting line C_{q} and the second connecting line E_{q}. In the conventional art, the voltage bias for driving the micro LED (the first voltage and the second voltage) are introduced into the display panel through the same side of the display panel. Accordingly, the pixel away from the signal input terminal A will generate voltage drop due to the inherent impedances of the connecting line of the driving voltage and the common electrode layer of the common voltage, so that the voltage bias ΔV between the driving transistor 22 and the micro LED 21 are smaller as the distances between the pixels and the signal input terminal A increase, thereby causing the uneven brightness phenomenon. However, in the micro LED display device 1 of this embodiment, the first voltage V_{DD} outputted from the power supply circuit 122 is introduced into the display panel 11 through the first side A1 of the display panel 11, the second voltage V_{SS} outputted from the power supply circuit 122 is introduced into the display panel 11 through the second side A2 of the display panel 11, and the voltage bias between the first voltage V_{DD} and the second voltage V_{SS} is in positive correlation to a brightness of the connected pixel. In different pixels in each of the pixel group units P₁˜Pₙ along the second direction D2, the voltage differences between the voltages applied to the driving transistor 22 and the micro LED 21 (i.e. the voltages applied to the first connection line C_{q} and the second connection line E_{q}) of different pixels almost the same regardless the distances between the signal input terminal A and the pixels. In addition, the voltage bias between the first voltage V_{DD} and the second voltage V_{SS} of pixels at different locations are approximating to each other. As a result, the micro LED display device 1 of this embodiment can improve the uneven brightness phenomenon of the micro LEDs 21 in the pixel group units P₁˜Pₙ of the conventional art, thereby improving the display quality of the micro LED display device 1.

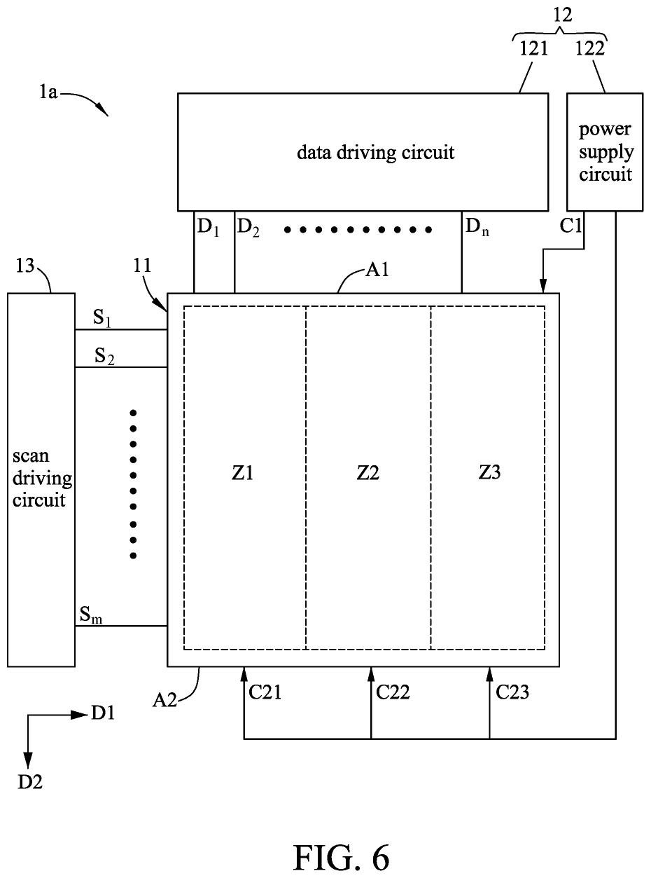

FIG. 6 is a schematic diagram showing a micro LED display device according to another embodiment of this disclosure. To be noted, for the sake of simplifying the drawing, some components are not shown in FIG. 6 (e.g. the pixel group units and the pixels are not shown).

As shown in FIG. 6, the configurations and connections of components of the micro LED display device 1a of this embodiment are mostly the same as those of the micro LED display device 1 of the previous embodiment. Different from the micro LED display device 1, the power supply circuit 122 of the micro LED display device 1a outputs the second voltage V_{SS}, which is introduced into the display panel 11 from the second side A2 of the display panel 11 through a plurality of main traces (e.g. three main traces C21, C22 and C23), and then transmitted to the pixel group units through the second connecting lines disposed inside the display area. In addition, the pixel group units of the display panel 11 of this embodiment can be divided into a plurality of zones (e.g. three zones Z1, Z2 and Z3) in the first direction D1, and the main traces (C21, C22 and C23) are disposed corresponding to the zones (Z1, Z2 and Z3). In other words, the main trace C21 connects all the second connecting lines of the zone Z1, the main trace C22 connects all the second connecting lines of the zone Z2, and the main trace C23 connects all the second connecting lines of the zone Z3. In this embodiment, the main traces C21, C22 and C23 are disposed corresponding to the zones Z1, Z2 and Z3 in a one-by-one manner, but this disclosure is not limited thereto. For example, in other embodiments, one main trace can be disposed corresponding to multiple zones, or multiple main traces can be disposed corresponding to a single zone.

Specifically, in this embodiment, the second voltage V_{SS} applied from the main trace C21 is transmitted to the pixel group units in the zone Z1 through the corresponding second connecting lines, the second voltage V_{SS} applied from the main trace C22 is transmitted to the pixel group units in the zone Z2 through the corresponding second connecting lines, and the second voltage V_{SS} applied from the main trace C23 is transmitted to the pixel group units in the zone Z3 through the corresponding second connecting lines. Although the pixel group units of the display panel 11 are corresponding to the second connecting lines, the second connecting lines corresponding to the three zones Z1, Z2 and Z3 in the display area are not connected to each other. This design can improve the uneven brightness phenomenon of the pixels in three zones Z1, Z2 and Z3 along the first direction D1. Of course, in different embodiments, the second connecting lines corresponding to the three zones Z1, Z2 and Z3 in the display area can be connected to each other, and this disclosure is not limited.

In some embodiments, the amount of the main traces for transmitting the second voltage V_{SS} can be equal to the amount of the second connecting lines or the pixel group units, and they are correspondingly connected to each other in the one-by-one manner for transmitting the second voltage to the pixel group unit through the corresponding main trace and the corresponding second connecting line. That is, one main trace is corresponding to and connected to one second connecting line and one pixel group unit. To be noted, this disclosure is not limited thereto.

In summary, in the micro LED display device of this disclosure, the display panel comprises a plurality of pixel group units arranged side by side along a first direction, and each of the pixel group units comprises a plurality of pixels extending in a second direction, which is different from the first direction; and the driving circuit unit outputs a first voltage and a second voltage to the pixels of each pixel group unit of the display panel, wherein the first voltage is introduced into the display panel from the first side of the display panel, the second voltage is introduced into the display panel from the second side of the display panel, and the voltage bias between the first voltage and the second voltage is in positive correlation to a brightness of one of the connected pixels. Accordingly, the voltage bias for driving the micro LEDs, which are added in different pixels of each pixel group unit along the second direction, can have a small deviation, thereby minimizing the deviation of the brightness of the micro LEDs of each pixel group unit. Therefore, the micro LED display device of this disclosure can improve the uneven brightness phenomenon caused by the voltage drops of driving voltages, thereby improving the display quality.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

1. A micro light-emitting diode (LED) display device, comprising:
a display panel comprising a plurality of pixel group units arranged side by side along a first direction, wherein each of the pixel group units comprises a plurality of pixels extending in a second direction, the first direction is different from the second direction;
a driving circuit unit electrically connected to the display panel, wherein the driving circuit unit outputs a first voltage and a second voltage different from the first voltage to the pixels of each of the pixel group units of the display panel; and
a plurality of scan lines through which a scan signal is outputted to the plurality of pixels of the plurality of pixel group units, arranged side by side along the second direction and extending along the first direction,
wherein, the display panel has a first side and a second side disposed in the second direction and opposite to each other, the first voltage is introduced into the display panel from the first side, the second voltage is introduced into the display panel from the second side, and a voltage bias between the first voltage and the second voltage is in positive correlation to a brightness of one of the connected pixels,
wherein, the plurality of scan lines are disposed between the first side and the second side.

2. The micro LED display device of claim 1, wherein the first voltage is greater than the second voltage.

3. The micro LED display device of claim 1, wherein the first voltage is a driving voltage of the pixel group units, and the second voltage is a common voltage of the pixel group units.

4. The micro LED display device of claim 1, wherein the first voltage is applied along the second direction to the pixels of each of the pixel group units.

5. The micro LED display device of claim 4, wherein the second voltage is applied along a direction opposite to the second direction to the pixels of each of the pixel group units.

6. The micro LED display device of claim 1, wherein the display panel further comprises a plurality of first connecting lines extending along the second direction, and the first voltage is applied to the pixel group units through the first connecting lines.

7. The micro LED display device of claim 6, wherein one of the first connecting lines is disposed corresponding to one of the pixel group units.

8. The micro LED display device of claim 1, wherein the display panel further comprises a plurality of second connecting lines extending along the second direction, and the second voltage is applied to the pixel group units through the second connecting lines along a direction opposite to the second direction.

9. The micro LED display device of claim 8, wherein one of the second connecting lines is disposed corresponding to one of the pixel group units.

10. The micro LED display device of claim 8, further comprising:
at least one main trace arranged between the driving circuit unit and the second connecting lines, wherein the second voltage is introduced into the display panel from the second side through the at least one main trace.

11. The micro LED display device of claim 10, wherein the at least one main trace is connected to each of the second connecting lines.

12. The micro LED display device of claim 10, wherein the micro LED display device comprises a plurality of the main traces, the pixel group units are divided into a plurality of zones in the first direction, and the main traces are disposed corresponding to the zones.

13. The micro LED display device of claim 12, wherein each of the zones includes a plurality of the second connecting lines and electrically connects to one of the main traces.

14. The micro LED display device of claim 10, wherein the micro LED display device comprises a plurality of the main traces, and the main traces are disposed corresponding to the second connecting lines.

15. The micro LED display device of claim 1, further comprising:
a plurality of data lines, wherein the driving circuit unit comprises a data driving circuit and a power supply circuit, the data driving circuit outputs a data signal to the pixel group units through the data lines, and the power supply circuit outputs the first voltage and the second voltage.

16. The micro LED display device of claim 15,
wherein the driving circuit unit comprises a scan driving circuit electrically connected to the display panel and outputs the scan signal to the pixel group units through the scan lines.
